(19) United States
(12) Patent Application Publication
(10) Pub. No.: US 2005/0015799 A1
(43) Pub. Date: Jan. 20, 2005

(54) Apparatus and method for displaying out-of-band channel information in open cable system

(75) Inventor: Jung-kil Park, Seoul (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 10/884,922

(22) Filed: Jul. 7, 2004

(30) Foreign Application Priority Data
Jul. 18, 2003 (KR) 10-2003-0049159

(51) Int. Cl. H04N 7/16; H04N 7/10; H04N 7/025; G03F 3/10

(52) U.S. Cl. 725/32; 725/135; 725/136

(57) ABSTRACT

An apparatus and a method for displaying out-of-band information without turning on a TV or set-top box in an open cable system. A receiving unit receives an out-of-band signal transmitted from a headend and parses the signal. A storage unit stores the parsed data and a user's display setting. A processing unit loads the user's display setting from the storage unit and processes the data according to the user's display setting. A control unit further processes the processed data and causes the further processed data to be displayed on an auxiliary display or main display, wherein the auxiliary display displays the further processed data in a stand-by mode state.

This application is based on and claims priority from Korean Patent Application No. 10-2003-0049159 filed on Jul. 18, 2003 with the Korean Intellectual Property Office, the disclosure of which is incorporated herein in its entirety by reference.

### BACKGROUND OF THE INVENTION

1. Field of the Invention

The present invention relates to an apparatus and a method for displaying an electronic program guide (EPG), and more particularly, to an apparatus and a method for displaying out-of-band information without turning on a television (TV) or set-top box in an open cable system.

2. Description of the Prior Art

A conventional configuration related to the present invention will be described with reference to FIG. 1. A receiving unit 111 splits broadcast signals, which have been transmitted from a headend 100, into audio, video and additional information data, and then processes the audio, video and additional information data. A storage unit 112 stores the additional information data, such as EPG data, processed by the receiving unit 111 while a display unit 114 outputs the audio and video data. A control unit 113 informs a user that the EPG data has been received, and upon receipt of a user's request, displays the EPG data, which has been stored in the storage unit 112, at a predetermined position on a screen of the display unit 114 with a program currently displayed thereon.

Next, the operation of the conventional configuration will be described in more detail. First, a user activates a host 110 such as a set-top box, a digital TV, a computer or a combination thereof, which outputs audio, video and additional information data to the user based on digital TV broadcast signals received from the headend 100. When the user changes a channel using a remote control (not shown), the receiving unit 111 receives the digital TV broadcast signals from the headend 100 and parses the signals of the channel. In addition, the receiving unit 111 stores parsed program-related data, such as EPG data, in the storage unit 112. The audio and video signals are directly output via the display unit 114. Finally, when the user requests EPG data using the remote control, the control unit 113 causes EPG information regarding the channel, which has been stored in the storage unit 112, to be displayed on the display unit 114.

According to the conventional configuration described above, the host has ON and OFF operation modes. Here, the existing host cannot perform any operations or provide any services while in the OFF mode state. Furthermore, since existing EPG data includes only information regarding broadcast programs such as channel number, channel name, broadcast date, broadcast start time, program identification number and program description, it is difficult for a user to select a variety of information. Moreover, in order to search for channel information through the existing EPG, the host should be activated and manipulated by using the remote control. In addition, since the EPG data is displayed on a full screen or superposed/overlapped on images of a program, it is difficult to know the channel information in a simple and easy manner.

### SUMMARY OF THE INVENTION

The present invention is directed to overcoming the problems in the conventional configuration. An object of the present invention is to display a variety of information regarding broadcasts such as out-of-band system information (OOB SI) and point-of-deployment (POD) information without turning on a TV or set-top box in an open cable system.

Another object of the present invention is to provide a display device for allowing a user to variously select and view the latest program information for a desired channel, a current broadcast channel or impulse-pay-per-view (IPPV) according to various settings by the user.

A further object of the present invention is to allow a user to view channel information through a front panel display of a host in an OFF state by using a stand-by mode of an open cable system and to determine whether to watch TV.

According to an aspect of the present invention for achieving the objects, there is provided an apparatus for displaying out-of-band channel information in an open cable system, comprising a receiving unit for receiving an out-of-band signal transmitted from a headend and parsing the signal; and a control unit for processing the parsed data and causing the processed data to be displayed on an auxiliary display or main display, the auxiliary display displaying the parsed data in a stand-by mode state.

According to another aspect of the present invention, there is provided an apparatus for displaying out-of-band channel information in an open cable system, comprising a receiving unit for receiving an out-of-band signal transmitted from a headend and parsing the signal; a storage unit for storing the parsed data and a user's display setting; a processing unit for loading the user's display setting from the storage unit and processing the data according to the loaded, user's display setting; and a control unit for further processing the processed data and causing the further processed data to be displayed on an auxiliary display or main display, the auxiliary display displaying the further processed data in a stand-by mode state.

According to a further aspect of the present invention, there is provided a method of displaying out-of-band channel information in an open cable system, comprising the steps of receiving, by a receiving unit, an out-of-band signal transmitted from a headend; parsing the received out-of-band signal; and outputting the parsed data to an auxiliary display.

According to a still further aspect of the present invention, there is provided a method of displaying out-of-band channel information in an open cable system, comprising the steps of receiving, by a receiving unit, an out-of-band signal transmitted from a headend; parsing the received out-of-band signal; storing the parsed data in a storage unit; processing the data according to a user's display setting that has been loaded from the storage unit; and further processing the processed data and displaying them on an auxiliary display.

Contrary to the open cable system, there is no stand-by mode in case of terrestrial or satellite wave systems. As a result, in case of terrestrial or satellite waves, tuning should be made to acquire information on a current channel. Otherwise, two tuners should be provided and one of them should be continuously tuned to obtain information on entire channels. The present invention enables displaying of OOB data by using the stand-by mode in the open cable system without requiring an additional tuner. The term “stand-by mode” of the open cable system means a state where the display unit including a demultiplexer, a MPEG-2 decoder and a main display is in the OFF mode state, while the remainder of the host including the receiving unit is in the ON mode state.

### BRIEF DESCRIPTION OF THE DRAWINGS

The above and other objects, features and advantages of the present invention will become apparent from the following description of exemplary embodiments given in conjunction with the accompanying drawings, in which:

FIG. 1 shows a configuration of a conventional apparatus for displaying EPG data;

FIG. 2 shows a configuration of an apparatus for displaying out-of-band (OOB) data according to an exemplary embodiment of the present invention;

FIG. 3a shows an example of a conventional electronic program guide (EPG) screen;

FIG. 3b shows an example in which the current time and information regarding only currently broadcast programs and the remaining times of the programs are displayed in accordance with an exemplary embodiment of the present invention;

FIG. 3c shows an example in which information regarding currently broadcast pay-per-view programs is displayed in accordance with an exemplary embodiment of the present invention;

FIG. 4 illustrates the process of setting desired information to be displayed by a user according to an exemplary embodiment of the present invention; and

FIG. 5 illustrates the process of displaying OOB data according to an exemplary embodiment of the present invention.

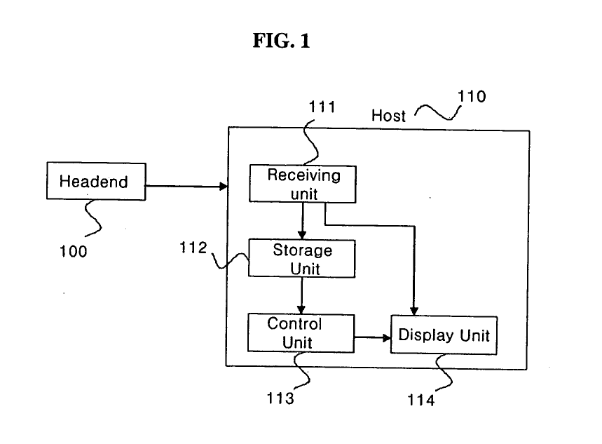

### DETAILED DESCRIPTION OF THE INVENTION

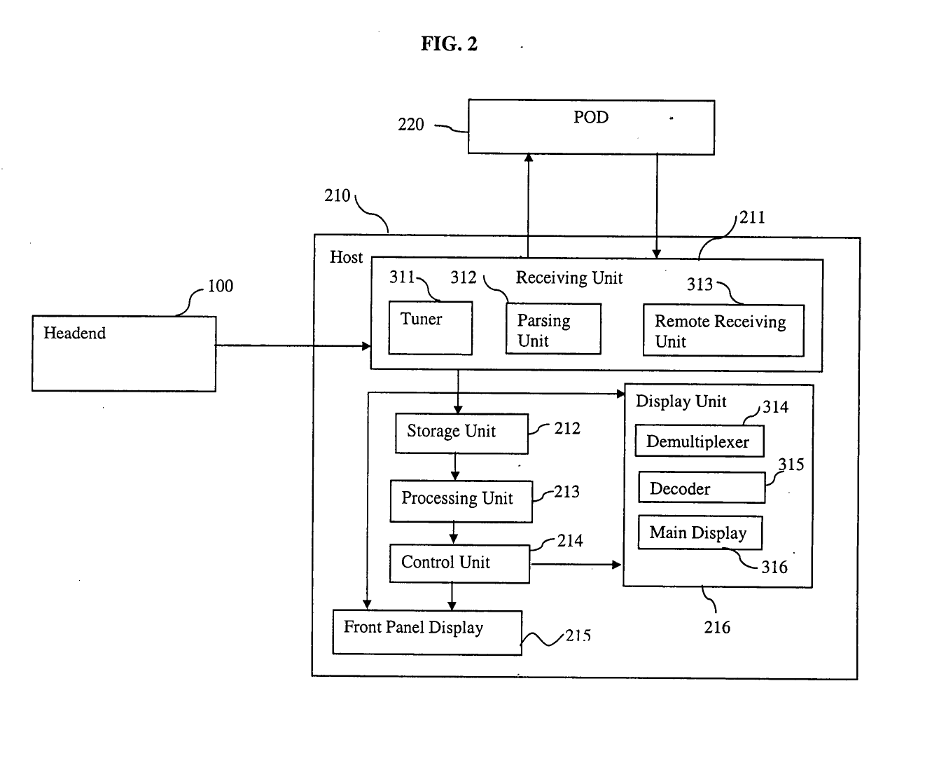

Hereinafter, exemplary embodiments of an apparatus and method according to the present invention will be described in detail with reference to the accompanying drawings. FIG. 2 shows the configuration of an apparatus for displaying out-of-band (OOB) data according to an exemplary embodiment of the present invention.

A broadcast station or external program provider transmits a broadcast signal from a headend 100. The broadcast signal is divided into an in-band (INB) signal that is an information signal within the bandwidth of an allocated channel, and an out-of-band (OOB) signal that is an information signal outside the bandwidth of the channel. The INB signal is received through a tuner 311 in a receiving unit 211 of a host 210 and then sent to a point-of-deployment (POD) 220. The POD 220 sends the INB signal back to the receiving unit 211 of the host 210, and the receiving unit 211 in turn delivers the INB signal to a display unit 216. The display unit 216 comprises a demultiplexer 314, a MPEG-2 decoder 315, and a main display 316. The INB signal is split into video, audio and EPG data signals by the demultiplexer 314. When the split information passes through the MPEG-2 decoder 315, a storage unit 212 stores the EPG data information that has been split by the demultiplexer 314, and the video and audio information is output by the main display 316. Then, a control unit 214 informs a user that the EPG data has been received. As for methods of informing the user that EPG data has been received, any method using messages, characters, sounds or the like may be employed as long as the user can recognize them. In this case, if the user wants to view current EPG data, the user presses a predetermined key on a remote control (not shown) to request the currently received EPG data information. A remote receiving unit 313 of the receiving unit 211 receives a signal from the remote control and outputs a signal to request displaying of the stored, currently received EPG data on the main display 316. In response to the signal received from the remote control, the control unit 214 then displays the EPG data stored in the storage unit 212 at a predetermined position on a screen of the main display 316 on which a program is currently displayed. Since such a method of receiving and displaying an INB signal can use conventional technology, a detailed description thereof will be omitted.

The OOB signal contains channel-related information and additional other information. More specifically, the OOB signal may contain an electronic program guide (EPG), impulse-pay-per-view (IPPV), Data, an emergency alert system (EAS), video on demand (VOD), web, e-mail information and the like. The EPG data corresponds to system information, i.e. channel information, and the IPPV refers to information on pay-per-view channels. The Data corresponds to information other than the channel information, which may include advertisement information transmitted from a broadcast station. In addition, the EAS corresponds to messages that a broadcast station wishes to urgently inform viewers of (for example, war or earthquake warnings), and the VOD corresponds to information regarding video-on-demand.

The POD 220 is not a module incorporated in the host but a stand-alone device. Accordingly, the POD 220 has a separate CPU and performs its own independent functions. The signal sent to the POD 220 is decrypted in the POD 220. Generally, a broadcast station encrypts broadcast information and then transmits encrypted information, and the POD 220 receives and decrypts the encrypted information. When the information decrypted by the POD 220 is sent back to the host 210, the host 210 can receive and use this information. Although the POD 220 decrypts the broadcast information that has been encrypted by the broadcast station, the POD 220 performs its own encryption for the broadcast information and sends the encrypted information to the host 210 so that the broadcast information can be used only by an authorized, relevant host but not by other hosts. This is to protect contents and provide services only to those who have purchased the POD.

Referring again to FIG. 2, the components involved in processing the OOB signal will be described in view of their features. The OOB signal transmitted from the headend 100 is received through the tuner 311 in the receiving unit 211 of the host 210 and then sent to the POD 220. The POD 220 decrypts the OOB signal and encrypts the OOB signal by using its own functions. Thereafter, if the POD 220 sends the OOB signal in MPEG format to the receiving unit 211 of the host 210, a parsing unit 312 of the receiving unit 211 parses the OOB signal to generate OOB data. Although the parsed OOB data may be directly displayed on the main display 316 of the display unit 216, the parsed OOB data is stored in the storage unit 212 according to an exemplary embodiment of the present invention. The storage unit 212 may be a separate storage device, a flash memory or the like. Furthermore, the storage unit 212 may store a user's display setting that is input through the manipulation of a remote control by a user.

A processing unit 213 retrieves the user's display setting from the storage unit 212 and then processes the OOB data according to the retrieved user's display setting. Subsequently, the processing unit 213 delivers the processed data to the control unit 214. The control unit 214 causes the processed data to be displayed on a front panel display 215 or the main display 316 of the display unit 216 during the processing step. The front panel display 215 is a display device that is implemented separately from the main display 316 of the host such as a TV or set-top box, using LEDs or an LCD provided in the front of the host 210. Such a front panel display 215 is only an example of an auxiliary display that is distinct from the main display 316. Any display devices that can be activated even in a stand-by mode state may be the auxiliary display devices.

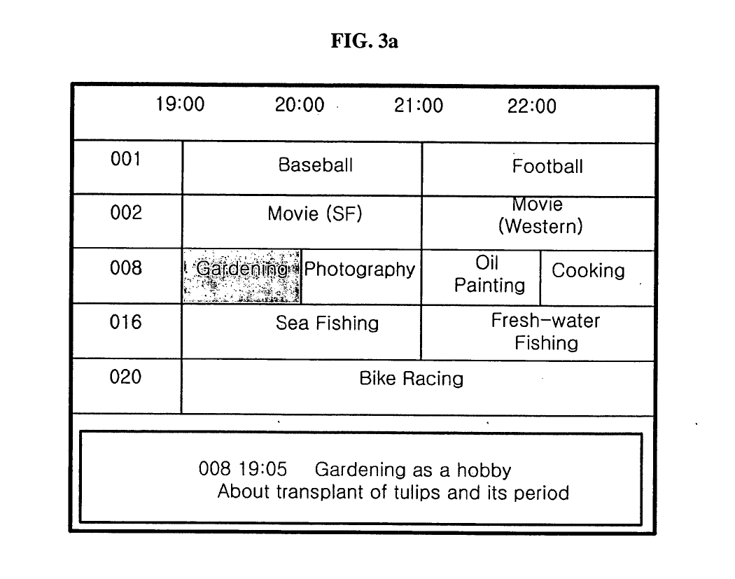

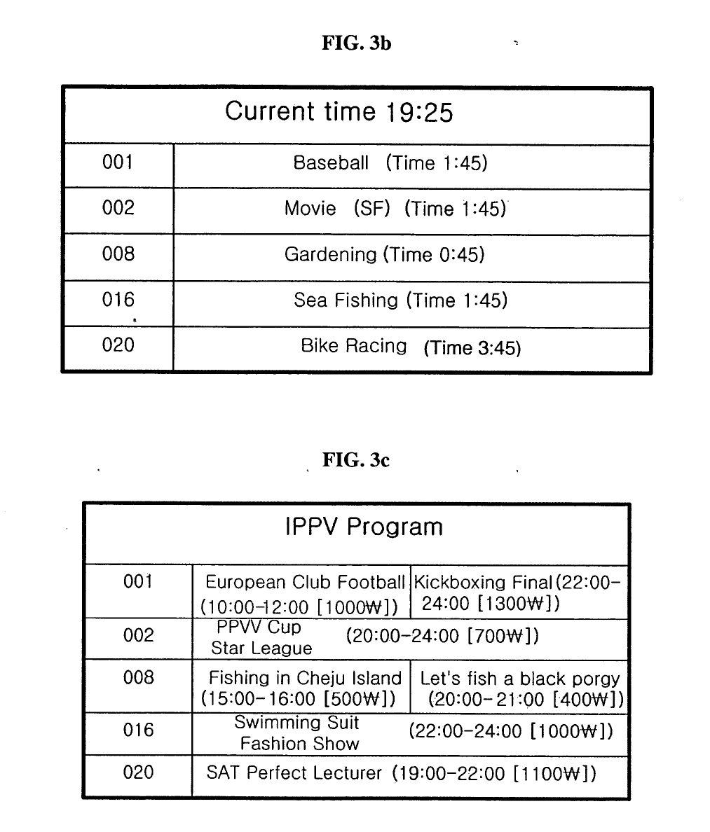

FIG. 3a shows an example of a conventional EPG screen. As illustrated in FIG. 3a, the conventional EPG contains only information on broadcast programs such as channel number, channel name, broadcast date, broadcast start time, program identification number, and program description. However, in addition to the aforementioned broadcast program information, the present invention enables additional information on EPG, IPPV, Data, EAS, VOD, web, e-mail and the like to be processed and displayed even when the host 210 is in the OFF state.

FIG. 3b shows an example in which the current time and information regarding only currently broadcast programs and the remaining times of the currently broadcast programs are displayed in accordance with an exemplary embodiment of the present invention. OOB SI and POD information are displayed according to the user's display setting. The user may want to view all information such as channel number, channel name and broadcast date or selectively view only some of them. As shown in FIG. 3b, the remaining times of programs of currently broadcast channels may be displayed while displaying the current time. As for the channel information to be displayed, it may include information on all channels, channels that have been set as favorite channels by the user, or a single specific channel.

FIG. 3c shows an example in which information on currently broadcast pay-per-view programs is displayed in accordance with the present invention. The information on the IPPV may also be displayed using the POD information. Information on pay-per-view programs associated with all channels, channels that have been set as favorite channels, or several specific channels may also be displayed.

The user can obtain channel information such as OOB SI and POD information shown in FIGS. 3a to 3c in the state where the host is OFF without turning on a TV, and thus, the user can beforehand determine whether to watch a program on a channel. Therefore, while watching TV, the user can directly select a channel by using the channel information displayed on the front panel display 215 without executing an EPG superposed/overlapped on the screen of the TV. This allows the user to watch TV in an efficient and economic manner. In addition to the channel information, the user can also be provided with other information. For example, it would be more advantageous that the user can watch reports on emergency news (e.g. war or earthquake warnings) such as EAS information, or advertisements using the Data information through the front panel display 215 without turning on the TV.

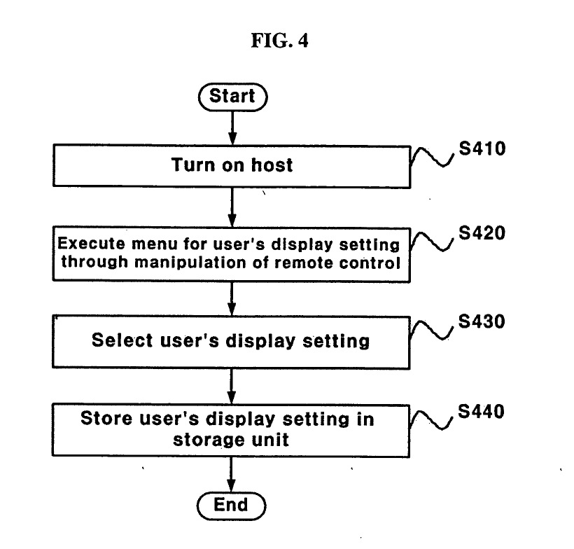

FIG. 4 illustrates the process of setting desired information to be displayed by the user according to the present invention. First, the user turns on the host 210 (S410). Then, the user executes a menu for setting information to be displayed on the front panel display 215 by manipulating a remote control or using other methods (S420). The menu may be selected among several default menus or configured one by one according to the user's preference. The input through the remote control may be considered as being received through a remote receiving unit that is separate from the receiving unit 211 in FIG. 2. However, it will be considered in the present invention that the remote receiving unit 313 is also included in the receiving unit 211. Subsequently, the user selects a desired user's display setting by manipulating the remote control or using other methods (S430). The resultant setting is stored in the storage unit 212 (S440). Thereafter, the processing unit 213 processes OOB data according to the user's display setting as stored, and the control unit 214 then causes the processed data to be displayed on the front panel display 215.

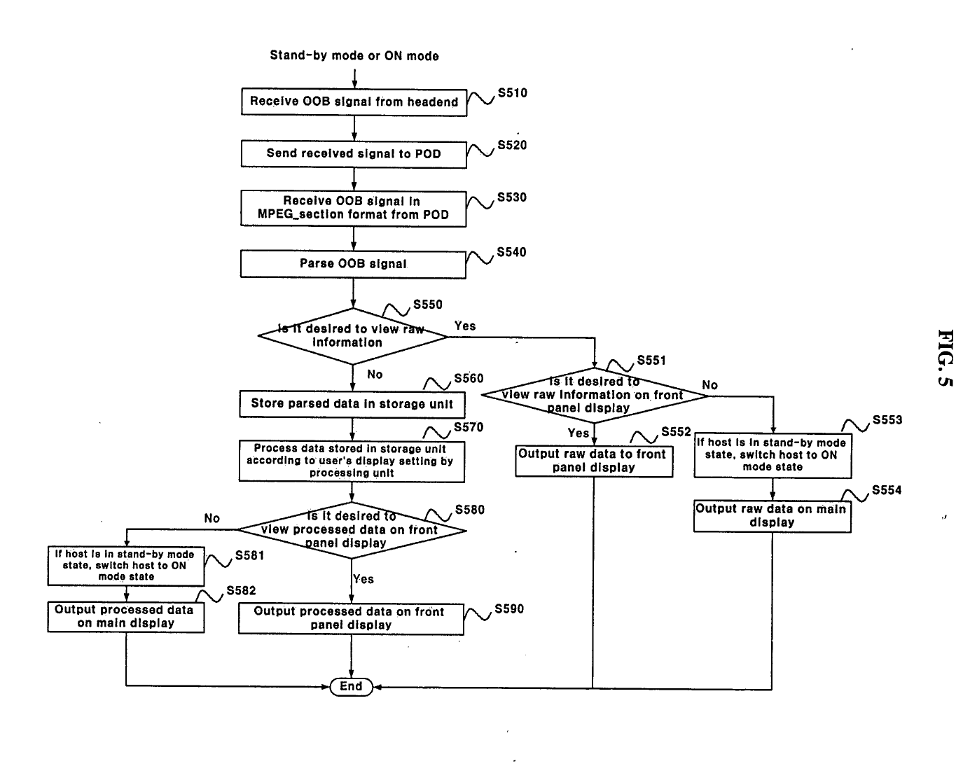

FIG. 5 illustrates the process of displaying the OOB data according to the present invention. Although the process is preferably performed when the host 210 is in the stand-by mode state, the process may be performed when the host 210 is in the ON mode state.

First, an OOB SI signal transmitted from the headend is received through the tuner 311 in the receiving unit 211 of the host 210 (S510). The received OOB signal is sent to the POD 220 (S520). The OOB signal is subjected to decryption in the POD 220 and then sent back to the receiving unit 211 of the host 210 in MPEG format (S530). The parsing unit 312 of the receiving unit 211 parses the OOB signal received from the POD 220 (S540). The parsed data includes OOB data and POD data, which may be either directly displayed in a raw format or displayed after being processed in the processing unit 213. As a result, if it is desired to view the OOB data in the raw format, i.e. in the same format as transmitted from the headend 100, a selection is performed as to whether to display the data on the front panel display 215 or the main display 316 of the display unit 216 (S551). The selection may be performed by the user either remotely through a remote control or directly through a user input unit attached to the host 210. When it is desired to view the OOB data through the front panel display 215, the OOB data is output directly to the front panel display 215 (S552). However, when it is desired to view the OOB data through the main display 316 of the display unit 216 in the stand-by mode state, the host 210 is first switched to the ON mode state (S553) and information is output to the main display 316 of the display unit 216 (S554).

When it is desired to display the parsed data in a processed format, the parsed data is first stored in the storage unit 212 (S560). Then, the processing unit 213 processes the data stored in the storage unit 212 by referring to the user's display setting that has been stored in the storage unit 212 through the process of configuring the user's display setting illustrated in FIG. 4 (S570). When it is desired to view the processed information through the front panel display 215, the information is output to the front panel display 215 (S590). However, when it is desired to view the processed data through the main display 316 of the display unit 216 in the stand-by mode state, the host 210 is switched from the stand-by mode state to the ON mode state (S591) and the processed data is then output to the main display 316 of the display unit 216 (S592).

According to the present invention, OOB SI can always be provided since POD and OOB SI circuits remain in an ON mode state even when a host in an open cable system is in a stand-by mode state. Therefore, even when the display unit of the host remains in an OFF mode state, a user can obtain channel information and beforehand determine whether to watch a program over a channel without turning on a TV.

Further, according to the present invention, there is convenience in that only channel information desired by a user is processed using OOB SI and then displayed according to a user's display setting. Moreover, the user can easily obtain information on pay-per-view channels since IPPV channel information can be represented using POD information.

Furthermore, according to the present invention, a user can obtain all information regarding broadcast channels by viewing only channel information displayed on the front panel display even while watching TV. Thus, there is no need for executing an EPG superposed/overlapped on the screen of the TV, and the inconvenience of manipulating the EPG using a remote control can be eliminated.

Although the embodiments of the present invention have been described with reference to the accompanying drawings, it will be understood by those skilled in the art that the present invention is not limited thereto and various changes and modifications can be made without departing from the scope and technical spirit of the invention. Therefore, it should be noted that the embodiments are merely illustrative and not exhaustive. The scope of the invention is defined by the appended claims rather than the detailed description. Various changes and modifications derived from the language of the claims and equivalents thereof should be construed as falling within the scope of the invention.

1. An apparatus for displaying out-of-band channel information in an open cable system, the apparatus comprising:
a main display;
an auxiliary display;
a receiving unit for receiving an out-of-band signal transmitted from a headend and parsing the out-of-band signal to generate parsed data; and
a control unit for processing the parsed data to generate processed data and causing the processed data to be displayed on at least one of the auxiliary display and the main display, said auxiliary display displaying the parsed data when the apparatus is in a stand-by mode state where at least the main display is in an OFF state.

2. The apparatus as claimed in claim 1, wherein the receiving unit comprises:
a tuner for receiving the out-of-band signal transmitted from the headend;
a parser for parsing the out-of-band signal to generate out-of-band data; and
an input receiving unit for receiving an input from a user to create a user display setting for processing the out-of-band data.

3. The apparatus as claimed in claim 1, further comprising:
a point-of-deployment (POD) device for receiving the out-of-band signal from the receiving unit, decrypting the out-of-band signal and sending the out-of-band signal which has been decrypted to the receiving unit, wherein the receiving unit parses the out-of-band signal received from the POD device to generate the parsed data.

4. The apparatus as claimed in claim 1, further comprising a display unit which comprises the main display, the display unit displaying the parsed data or the processed data on the main display in an ON mode state.

5. The apparatus as claimed in claim 4, wherein the display unit further comprises:
a demultiplexer for splitting an in-band signal transmitted from the headend into video, audio and electronic program guide (EPG) data; and
a decoder for decompressing the video and audio;
wherein the main display displays the parsed data, the processed data or the EPG data split from the in-band signal in the ON mode state.

6. The apparatus as claimed in claim 1, wherein the parsed data or the processed data displayed on the auxiliary display includes pay-per-view channel information.

7. The apparatus as claimed in claim 1, wherein the parsed data or the processed data displayed on the auxiliary display includes emergency notification messages.

8. The apparatus as claimed in claim 1, wherein the data-displayed on the auxiliary display includes advertisement messages.

9. The apparatus as claimed in claim 1, wherein the auxiliary display comprises a front panel display.

10. An apparatus for displaying out-of-band channel information in an open cable system, the apparatus comprising:
a main display;
an auxiliary display;
a receiving unit for receiving an out-of-band signal transmitted from a headend and parsing the out-of-band signal to generate parsed data;
a storage unit for receiving the parsed data from the receiving unit and storing the parsed data and a user display setting;
a processing unit for receiving the user display setting and the parsed data from the storage unit and processing the parsed data according to the user display setting to generate processed data; and
a control unit for receiving the processed data from the processing unit, further processing the processed data to generate further processed data and causing the further processed data to be displayed on at least one of the auxiliary display and the main display, said auxiliary display displaying the parsed data or the further processed data when the apparatus is in a stand-by mode state where at least the main display is in an OFF state.

11. The apparatus as claimed in claim 10, wherein the receiving unit comprises:
a tuner for receiving the out-of-band signal transmitted from the headend;
a parser for parsing the out-of-band signal to generate out-of-band data; and
an input receiving unit for receiving an input from a user to create a user display setting for processing the out-of-band data.

12. The apparatus as claimed in claim 10, further comprising:
a point-of-deployment (POD) device for receiving the out-of-band signal from the receiving unit, decrypting the out-of-band signal and sending the out-of-band signal which has been decrypted to the receiving unit, wherein the receiving unit parses the out-of-band signal received from the POD device to generate the parsed data.

13. The apparatus as claimed in claim 10, further comprising a display unit which comprises the main display, the display unit displaying the parsed data or the further processed data on the main display in an ON mode state.

14. The apparatus as claimed in claim 13, wherein the display unit further comprises:
a demultiplexer for splitting an in-band signal transmitted from the headend into video, audio and electronic program guide (EPG) data; and
a decoder for decompressing the video and audio;
wherein the main display displays the parsed data, the further-processed data or the EPG data split from the in-band signal in the ON mode state.

15. The apparatus as claimed in claim 10, wherein the parsed data or the further processed data displayed on the auxiliary display includes pay-per-view channel information.

16. The apparatus as claimed in claim 10, wherein the parsed data or the further processed data displayed on the auxiliary display includes emergency notification messages.

17. The apparatus as claimed in claim 10, wherein the data displayed on the auxiliary display includes advertisement messages.

18. The apparatus as claimed in claim 10, wherein the auxiliary display comprises a front panel display.

19. A method for displaying out-of-band channel information on a main display and an auxiliary display of a host apparatus in an open cable system, the method comprising:
receiving, by a receiving unit, an out-of-band signal transmitted from a headend;
parsing the out-of-band signal received by the receiving unit to generate parsed data; and
displaying the parsed data on the auxiliary display.

20. The method as claimed in claim 19, further comprising:
configuring a user display setting based on an input from a user;
storing the user display setting as configured in a storage unit;
processing the parsed data based on the stored user display setting to generate processed data; and
displaying the processed data on the auxiliary display or the main display.

21. The method as claimed in claim 19, further comprising:
transferring the out-of-band signal from the receiving unit to a point-of-deployment (POD) device; and
decrypting the out-of-band signal and sending the out-of-band signal which has been decrypted to the receiving unit,
wherein the parsing step comprises parsing the out-of-band signal received by the receiving unit from the POD device to generate the parsed data.

22. The method as claimed in claim 19, further comprising displaying the parsed data on the main display.

23. The method as claimed in claim 19, wherein the respective steps are performed when the host device is in a stand-by mode state where at least the main display is in an OFF state.

24. The method as claimed in claim 19, wherein the auxiliary display comprises a front panel display.

25. A method for displaying out-of-band channel information on a main display and an auxiliary display of a host apparatus in an open cable system, the method comprising:
receiving, by a receiving unit, an out-of-band signal transmitted from a headend;
parsing the out-of-band signal to generate parsed data;
storing the parsed data in a storage unit;
processing the processed data according to a user display setting that has been stored in the storage unit to generate processed data; and
further processing the processed data to generate further processed data; and
displaying the further processed data on the auxiliary display.

26. The method as claimed in claim 25, further comprising:
configuring a user display setting based on an input from a user; and
storing the user display setting as configured in a storage unit,
wherein said processing step comprises processing the parsed data based on the stored user display setting to generate the processed data.

27. The method as claimed in claim 25, further comprising:
transferring the out-of-band signal form the receiver unit to a point-of-deployment (POD) device; and
decrypting the out-of-band signal and sending the decrypted signal back which has been decrypted to the receiving unit,
wherein the parsing step comprises parsing the out-of-band signal received by the receiving unit from the POD device to generate the parsed data.

28. The method as claimed in claim 25, further comprising the step of displaying the further processed data on the main display.

29. The method as claimed in claim 25, wherein the respective steps are performed when the host device is in a stand-by mode state where at least the main display is in an OFF state.

30. The method as claimed in claim 25, wherein the auxiliary display comprises a front panel display.
